(19) United States
(12) Patent Application Publication
(10) Pub. No.: US 2023/0142133 A1
(43) Pub. Date: May 11, 2023

(54) SOLDERING APPARATUS

(71) Applicant: ERSA GmbH, Wertheim (DE)

(72) Inventors: Michael Haas, Schollbrunn (DE); Benedict Fleischmann, Neubrunn (DE); Alexander Diehm, Wertheim (DE); Lukas Thanhäuser, Würzburg (DE)

(73) Assignee: ERSA GmbH, Wertheim (DE)

(21) Appl. No.: 17/983,608

(22) Filed: Nov. 9, 2022

(30) Foreign Application Priority Data
Nov. 9, 2021 (DE) 20 2021 106 100.6

(51) Int. Cl. B23K 1/00

(52) U.S. Cl. CPC B23K 1/0016; B23K 2101/42

(57) ABSTRACT

A soldering apparatus, in particular a reflow soldering apparatus, for continuous soldering of printed circuit boards along a transport direction, having a process channel including a preheating zone, a soldering zone and a cooling zone, having fan units for circulating process gas in the process channel, wherein the fan units each comprise an electric fan motor and a fan wheel, and having at least one apparatus element, wherein the soldering apparatus can be operated in an operating mode in which the fan motors are controlled in such a way that they are operated at a constant or largely constant rotational speed, as a result of which process gas is conducted through the at least one apparatus element and is then drawn in again by the respective fan units. At least one and preferably a plurality of current measuring units are provided that, in the operating mode, measure the current strength consumed by the relevant fan motor over time, and in that at least one evaluation unit is provided and configured such that a control signal is generated by the at least one evaluation unit if the relevant measured current strength falls below or exceeds a threshold value.

### CROSS-REFERENCE TO RELATED APPLICATION

The present application relates and claims priority to German Patent Application No. 20 2021 106 100.6, filed Nov. 9, 2021, the entirety of which is hereby incorporated by reference.

### BACKGROUND

The invention relates to a soldering apparatus, in particular a reflow soldering apparatus, for continuous soldering of printed circuit boards along a transport direction, having a process channel comprising a preheating zone, a soldering zone and a cooling zone, having fan units for circulating process gas in the process channel, wherein the fan units each comprise an electric fan motor and a fan wheel, and having at least one apparatus element, wherein the soldering apparatus can be operated in an operating mode in which the fan motors are controlled in such a way that they are operated at a constant or largely constant rotational speed, as a result of which process gas is drawn in again through the at least one apparatus element and then by the respective fan units. The process gas can be guided along the printed circuit board before or after flowing through the apparatus element. The apparatus element can in particular be a filter element through which process gas is passed to separate particles and condensate, a heat exchanger for heating or cooling process gas, a channel for conducting process gas, and/or any other component through which process gas is conducted. Such apparatus elements have in common that they are subject to contamination by particles present in the process gas and condensate forming, which can lead to an increased flow resistance of the process gas.

Reflow soldering apparatuss can be used to solder what are known as SMD components (Surface Mounted Devices) onto the surface of printed circuit boards by means of solder paste. The solder paste, which is in particular a mixture of metal soldering granules, flux and paste-like components, is applied or printed onto the surface of the printed circuit boards for reflow soldering. Subsequently, the components to be soldered are placed in the solder paste. In the reflow soldering process, the soldered object, i.e., the assembly consisting of a printed circuit board, solder paste and components to be soldered, is preheated along the process channel in a preheating zone and heated in a soldering zone to a temperature above the melting point of the solder paste. As a result, the solder paste melts and the solder joints are formed. In a cooling zone, if one is present, the soldered object is cooled until the melted solder solidifies before it is removed from the reflow soldering apparatus.

Soldering apparatuss for continuous soldering of printed circuit boards are known from DE 10 2019 128 780 A1, DE 10 2019 125 981 A1 and DE 10 2005 055 283 A1.

In the case of reflow soldering apparatuss, the process channel is generally formed by two channel halves, one upper and one lower channel half. The lower channel half is provided in or on a main body, and the upper channel half is provided in or on a cover hood. Further components, such as nozzle plates, fan units, air ducts guiding the process gas, filter elements and/or cooling elements, are generally provided in or on the process channel or in or on the main body and in or on the cover hood. Overall, a desired temperature profile is thus provided along the transport direction in the process channel, wherein the process gas is blown into the process channel, extracted therefrom, in particular cooled in the cooling zone, cleaned and fed back to the process channel.

In particular in the cooling zone, condensate is formed when the process gas cools, which condensate can cause contamination of the machine. It is known from the prior art to determine flow resistances within soldering apparatuss by means of load cells, flow measurement sensors and/or differential pressure measuring methods, which makes additional components and additional wiring effort necessary within the soldering apparatus.

### SUMMARY OF THE INVENTION

The object of the invention is to provide a soldering apparatus in which, in particular, the cooling zone is advantageously designed such that impurities are detected in good time.

This object is achieved by a soldering apparatus. Consequently, it is provided in particular in the cooling zone that at least one current measuring unit, in particular provided in or on the fan motor, and preferably a plurality of current measuring units are provided that, in the operating mode, measure the current strength consumed by the relevant fan motor over time and that at least one evaluation unit is provided and configured such that a control signal is generated by the at least one evaluation unit if the relevant measured current strength falls below or exceeds a threshold value.

Thus, without additional pressure sensors or flow measurement sensors, an increase in the flow resistance of the process gas can be indirectly inferred, wherein an increased flow resistance is associated with an increased degree of contamination of the machine. The degree of contamination can consequently be determined in a simple manner and nevertheless reliably.

If the fan motors are operated at constant or largely constant rotational speeds in the operating mode, an increase in the flow resistance leads to a decrease in the current strength consumed by the fan motors. If the current strength consequently falls below the threshold value at a constant speed, it is possible to deduce an increased degree of contamination, in particular of the filter element. The flow resistance is generally increased because in particular the filter element becomes clogged with particles and condensate contained in the process gas after a certain period of operation of the soldering apparatus.

Furthermore, it is advantageous if the at least one evaluation unit is further configured in such a way that further control signals are generated by the at least one evaluation unit if the measured current strength falls below or exceeds further threshold values. Consequently, a plurality of threshold values can be specified, wherein a control signal is then generated depending on whether the relevant threshold value is fallen below or exceeded. Different degrees of contamination can be detected and indicated as a result.

Furthermore, it is advantageous if the relevant threshold value or the threshold values are proportional to a degree of contamination of the relevant apparatus element. As a result, different degrees of contamination of the relevant apparatus element can be detected. If the apparatus element is a filter element, then the filter element can comprise a non-woven filter or filter granules.

Furthermore, it is conceivable that the relevant threshold value or the threshold values are proportional to a degree of contamination of a nozzle plate through which process gas is conducted before it flows onto the printed circuit board. A uniform air flow is provided with the nozzle plates. The nozzle plates have a plurality of nozzle openings that can also be contaminated. Overall, different degrees of contamination of the nozzle plate can be detected communicated.

According to the invention, it can also be provided that the at least one evaluation unit is further configured in such a way that, when the relevant control signal is generated, the relevant control signal is brought to the attention of an operator or a machine controller, and/or that steps for cleaning or for exchanging the at least one apparatus element are initiated. As a result, an operator can obtain information about the relevant degree of contamination. Accordingly, a superordinate machine controller can be informed about the degree of contamination, and corresponding measures can be initiated.

### BRIEF DESCRIPTION OF THE DRAWINGS

Further details and advantageous embodiments of the invention can be found in the following description, on the basis of which an embodiment of the invention is described and explained in more detail.

In the drawings:

FIG. 1 shows a reflow soldering apparatus in a side view obliquely from the front with a closed cover hood;

FIG. 2 is a front view of the reflow soldering apparatus according to FIG. 1; and

FIG. 3 is a cross section through the cooling zone of the reflow soldering apparatus according to FIG. 1.

### DETAILED DESCRIPTION

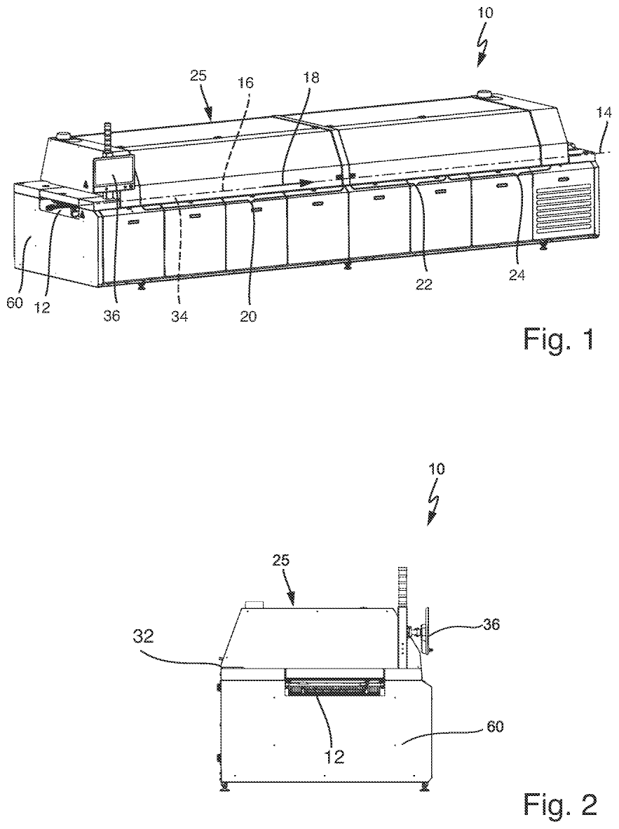

FIG. 1 shows a reflow soldering apparatus 10 for continuous soldering of soldered objects. The reflow soldering apparatus 10 has an inlet 12 and an outlet 14, wherein the soldered object to be soldered reaches the reflow soldering apparatus 10 via the inlet 12 and is discharged from the reflow soldering apparatus 10 via the outlet 14. The soldered object is transported along a transport direction 18 through a process channel 16 indicated in FIG. 1. A preheating zone 20, a soldering zone 22 and a cooling zone 24 are provided in the process channel 16.

As is clear from FIGS. 1 and 2, a communication unit 36 is provided with a screen and an input device by means of which it is possible to communicate with a machine controller of the reflow soldering apparatus 10.

The soldered object, i.e., the printed circuit board provided with the solder paste and equipped with electronic components, is first heated in the preheating zone 20 to a temperature below the melting temperature of the solder paste. In the soldering zone 22, the printed circuit board is heated for a certain duration to a process temperature above the melting point of the solder paste, such that the solder paste melts in the soldering zone in order to solder the electronic components to the printed circuit board. In the cooling zone 24, the soldered object is cooled such that the liquid solder solidifies before the soldered object is removed at the outlet 14 of the reflow soldering apparatus 10.

A transport system 34 is provided inside the reflow soldering apparatus 10 for transporting the printed circuit boards along the transport direction 18.

As is clear from FIG. 2, the reflow soldering apparatus 10 has a cover hood 25. The cover hood 25 can be pivoted open about a hood axis 32 extending parallel to the transport direction 18. By pivoting open the cover hood 25, the interior of the process channel 16 and the transport system 34 are accessible in order to optically inspect, maintain, clean, set up, replace, and optionally repair them.

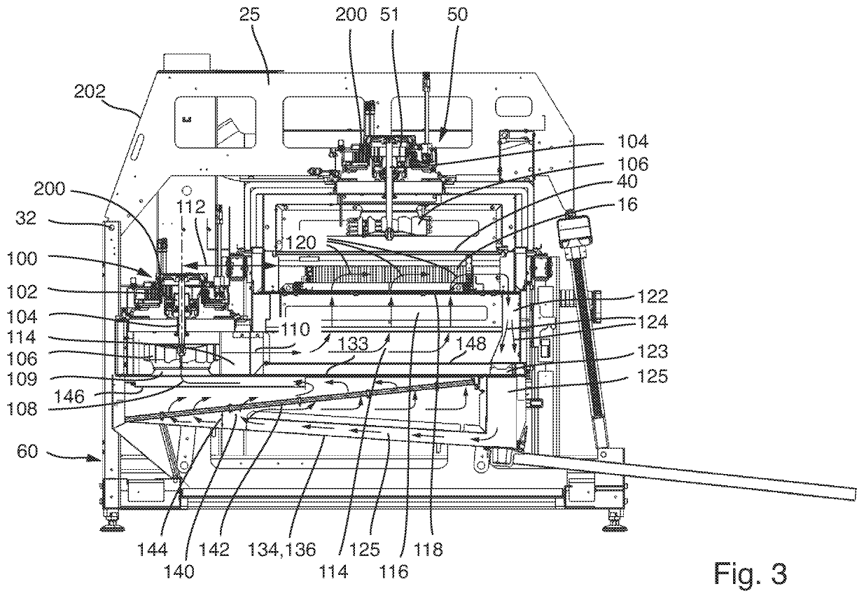

As is clear from the section according to FIG. 3 through the cooling zone 24, a plurality of fan units 50 having fan motors 51 are located above the process channel 16, which are provided to generate a provided air flow in the process channel 16. The fan units 50 in the preheating zone 20 and the process zone 22 can additionally have heating elements in order to provide a predetermined temperature. By means of the fan units 50 or the fan motors 51 thereof, correspondingly heated or cooled process gas is introduced from above through a nozzle plate 40 into the process channel 16.

As is also clear from the section according to FIG. 3 through the cooling zone 24, a plurality of fan units 100 arranged behind one another in the transport direction 18 are provided in the main body 60 in the transport direction 18 laterally next to the process channel 16 and in a plane below the transport channel 18, wherein only one fan unit 100 can be seen in the section according to FIG. 3. The fan units 100 correspond in terms of design to the fan units 50 and are situated in the transverse direction between the hood axis 32 and the process channel 16.

The fan units 50 or 100 each have a fan motor 51 or 102, a rotor shaft 104 driven by the relevant fan motor 51, 102 and a fan wheel 106 provided on the rotor shaft 104. The relevant fan wheel 106 is a radial fan wheel that, in the case of the fan motors 102 in FIG. 3, draws in process gas 108 axially from below from an intake region 109 and blows process gas 110 away in the radial direction. In this case, the relevant rotor shaft 104 is laterally spaced apart from the process channel 16 in the horizontal direction by the dimension 112. The relevant rotor shaft 104 extends in the vertical direction. The arrangement is in this case such that the relevant fan motor 102 or 51 is vertically above the relevant fan wheel 106.

During operation of the ventilator units 100, process gas 110 is blown into a guide channel 114 that extends substantially horizontally and that, following the fan wheel 106, in a transverse direction extending transversely to the transport direction 18, initially extends laterally next to and subsequently vertically below the process channel 16. Via the guide channel 114, the process gas is then blown vertically upward through a cooling element in the form of a heat exchanger 116, in which the process gas is further cooled, and blown into the process channel 16 from below through a lower nozzle plate 118. Consequently, the soldered object to be cooled is blown on from below inside the cooling zone 24.

The blown-in process gas 120 is guided toward the front longitudinal side on the soldered object provided in the process channel 14. There, the process gas 124 enters a lead-in channel 122 and is conducted vertically downward. In the region 123, the lead-in channel 122, which is provided on the main body 60, merges into an inlet channel 125. In the region of the bottom 128, the inlet channel 125 deflects process gas toward a cooling device 136 designed as a cooling plate 134.

As is clear from FIG. 3, the cooling plate 134 extends obliquely to the upper edge 133 or to the horizontal and slopes forward. The cooling plate 134 is cooled by ambient air in the present embodiment.

The inlet channel 125 opens on the rear side into a filter region 140. A apparatus element in the form of a filter element 142 is provided in the filter region 140. The filter element 142, which can provide a filter grid with a non-woven filter, for example, extends obliquely to the horizontal and is designed to slope backward. Overall, the plane in which the cooling plate 134 is located and the plane formed by the filter element 142 include an acute angle 144.

A shielding plate 146 is provided between the intake region 109 of the fan wheel 106 and the filter element 142 and shields the intake region 109 of the fan wheel 106. In order to cause the process gas that passes through the filter element 142 to be conducted toward the intake region of the relevant fan unit 100, a guide plate 148 is provided on the main body 60.

In order to determine a degree of contamination of the soldering apparatus 10 and, in particular, to determine a degree of contamination of the filter element 142 and or of the nozzle plate 118 or 40, current measuring units 200 are provided on the fan motors 51, 102, which current measuring units, in the operating mode in which the fan motors 102 are controlled in such a way that they are operated at a constant or largely constant rotational speed, measure the current strength consumed by the relevant fan motor 102 over time.

Furthermore, an evaluation unit 202 is provided that is configured in such a way that a control signal is generated by the at least one evaluation unit 202 if the relevant current strength measured by the current measuring units 200 falls below a predefinable threshold value. The evaluation unit 202 can communicate with the current measuring units 200 via connection cables (not shown) or via a radio connection.

Due to a clogging of the filter element 142 with residues and condensate, the flow resistance of the filter element 142 increases. At a constant rotational speed of the fan motors 51, 102, the current strength consumed by the fan motors 51, 102 decreases as the flow resistance increases. If the current strength falls below a first predefinable threshold value, this is detected by the evaluation unit 202 and a control signal is sent. The sending of the control signal can, for example, result in the detected degree of contamination being brought to the attention of an operator on the communication unit 36 or in it being signaled to the machine controller that measures for cleaning the soldering apparatus 10 and/or the filter element 142 are to be initiated.

In addition to the first threshold value, it is conceivable to provide further threshold values that are then each assigned to a further progressive degree of contamination. When the relevant further threshold value is fallen below, the relevant degree of contamination is then detected and indicated to the operator or the machine controller via corresponding control signals.

What is claimed is:

1. A soldering apparatus for continuous soldering of printed circuit boards along a transport direction, having a process channel comprising a preheating zone, a soldering zone and a cooling zone, having fan units for circulating process gas in the process channel, wherein the fan units each comprise an electric fan motor and a fan wheel, and having at least one apparatus element, wherein the soldering apparatus can be operated in an operating mode in which the fan motors are controlled in such a way that they are operated at a constant or largely constant rotational speed, as a result of which process gas is conducted through the at least one apparatus element and is then drawn in again by the respective fan units, characterized in that at least one and preferably a plurality of current measuring units are provided that, in the operating mode, measure the current strength consumed by the relevant fan motor over time, and in that at least one evaluation unit is provided and configured such that a control signal is generated by the at least one evaluation unit if the relevant measured current strength falls below or exceeds a threshold value.

2. The soldering apparatus according to claim 1, characterized in that the at least one evaluation unit is further configured in such a way that further control signals are generated by the at least one evaluation unit if the measured current strength falls below or exceeds further threshold values.

3. The soldering apparatus according to claim 1, characterized in that the relevant threshold value or the threshold values are proportional to a degree of contamination of the relevant apparatus element.

4. The soldering apparatus according to claim 1, characterized in that the relevant threshold value or the threshold values are proportional to a degree of contamination of a nozzle plate through which process gas is conducted before it flows onto the printed circuit board.

5. The soldering apparatus according to claim 1, characterized in that the at least one evaluation unit is further configured in such a way that, when the relevant control signal is generated, the relevant control signal is brought to the attention of an operator or a machine controller, and/or in that steps for cleaning or for exchanging the at least one apparatus element are initiated.

6. The soldering apparatus according to claim 1, characterized in that the apparatus element is designed as a filter element that in particular comprises a non-woven filter or a bed of granules, as a heat exchanger, as a channel and/or as a channel system.
